(19) United States
(12) Patent Application Publication
(10) Pub. No.: US 2018/0342638 A1
(43) Pub. Date: Nov. 29, 2018

(54) PHOTOVOLTAIC DEVICE

(71) Applicant: AGC GLASS EUROPE, Louvain-La-Neuve (BE)

(72) Inventors: Thomas LAMBRICHT, Perwez (BE); Benoit POOT, Petit-Enghien (BE); Benoit DOMERCQ, Brain-I'Alleud (BE)

(73) Assignee: AGC GLASS EUROPE, Louvain-La-Neuve (BE)

(21) Appl. No.: 15/778,510

(22) PCT Filed: Nov. 16, 2016
(86) PCT No.: PCT/EP2016/077850

§ 371 Date: May 23, 2018

(30) Foreign Application Priority Data
Nov. 25, 2015 (EP) 15196313.9

(51) Int. Cl. H01L 31/055; H01L 31/048

(52) U.S. Cl. CPC H01L 31/055; H01L 31/0488

(57) ABSTRACT

The invention relates to a photovoltaic device intended to convert into electricity incident radiation ϕ1 of a wavelength λ1 comprised between 280 and 1000 nm, comprising (i) an assembly comprising a glass sheet having two major faces f1 and f2, the face f1 being that via which the incident radiation penetrates into said assembly and said sheet being transparent to said incident radiation ϕ1; and a functional layer covering the major face f2 of the sheet and comprising a matrix in which are dispersed luminescent elements capable of absorbing said incident radiation ϕ1 of wavelength λ1 and of re-emitting it with a wavelength λ2 longer than λ1 and comprised between 800 and 1400 nm; and (ii) at least one photovoltaic cell at which the re-emitted radiation of wavelength λ2 arrives and which is sensitive to the wavelength λ2. In this device, the glass sheet has a coefficient of absorption at the wavelength λ2 lower than 3 m⁻¹. Such a device is applicable to the harvesting of solar energy in the architectural field.

### 1. FIELD OF THE INVENTION

The present invention generally relates to a device capable of converting incident radiation, especially solar radiation, into electricity by means of solar (or photovoltaic) cells, and more particularly to a device of this type that collects and concentrates more effectively the incident radiation for use by these cells. In particular, the invention relates to a photovoltaic (PV) device including one or more photovoltaic cells and an assembly of at least one glass sheet that is transparent to the incident radiation, and of a matrix in which are dispersed luminescent elements capable of absorbing the incident radiation and of re-emitting it with a longer wavelength, so that the wavelength of the new radiation falls in the zone of sensitivity of the one or more photovoltaic cells, the area of which is much smaller than that of each major face (generating area <<<collecting area).

Such a device is essentially, but not only, applicable to the harvesting of solar energy in the architectural field (device of the “building-integrated photovoltaics” or “BIPV” type).

### 2. SOLUTIONS OF THE PRIOR ART

Devices for concentrating radiation have been known about for a very long time and, for example, some have already been described in patents EP0004242B1, DE2628291 and U.S. Pat. No. 4,127,425.

In addition, in the article by E. WEBER and J. LAMBE published in “Applied Optics” volume 15, no. 10 pages 2299-2300, a radiation collector placed in an enclosure the upper surface of which is a window made of glass or of plastic and the lower surface of which is a mirror is described.

Patent EP0004242B describes a concentrator of solar radiation in which the radiation (λ1) passes through a matrix in which are distributed substances operating in luminescent cascade and capable of absorbing energy in a range of wavelengths (λ1) and of re-emitting it in a range of longer wavelengths (λ2), the latter range corresponding to the zone of optimal sensitivity of a solar photovoltaic cell at which said radiation arrives and the useful energy of which is thus amplified, wherein said matrix is located in an enclosure at least one portion of which, via which said radiation penetrates before passing through said matrix, is formed of a substance having a first refractive index (n1) on the side of the exterior of the enclosure, and a second refractive index (n2) on the side of said matrix, said second index being as high as possible with respect to said first index, the rest of said enclosure being opaque to said radiation arriving at the photovoltaic cells also located in the enclosure.

Patent DE2628291 describes a device for converting solar energy into electrical power, wherein the incident light is captured in a transparent or “concentrator” layer of higher refractive index than that of the surrounding medium and containing “fluorescent centres”; the light re-emitted is then directed towards conventional solar cells.

Patent U.S. Pat. No. 4,127,425 describes a device for collecting radiation made up of a luminescent planar layer and a solar cell placed on one of the lateral faces, the layer is formed by a matrix in which one or more luminescent agents are distributed. The other lateral faces and the lower face may be covered with mirrors. Radiation incident on the upper face is absorbed and re-emitted in an angle of 4π. By successive internal reflections, an intense flux of light of the desired wavelength is then channeled towards the end covered by the cell. The luminescent planar layers may be formed of glass or of a polymer in which luminescent agents are dispersed. These agents may directly emit light the energy of which is in the vicinity of the range to which the solar cell is sensitive; they may also emit this light by means of a cascade mechanism. In addition, in the device of U.S. Pat. No. 4,727,425, the one or more photovoltaic cells are positioned on an edge face of the luminescent layer that has been enlarged so as to increase the area of said edge face and to allow cells of larger area to be used and thus an increased generating area to be obtained.

In all the devices of the prior art, the absorption of the incident radiation and/or the re-emission of the new radiation occur(s) at least in part in the visible domain thus giving the device a colour in transmission and/or absorption that is not often desirable in architectural applications. In addition, these known devices have only a very modest area (of about 100 cm²) and/or a very low to moderate efficiency and/or are relatively unstable over time (especially because of the use of organic luminophores) and/or are not sufficiently transparent in the visible.

In order to make all these known devices actually envisageable in architectural applications, it is vital to significantly increase their size, typically to about 1 m by 2 m, or even 2 m by 4 m (or even more). Such dimensions then generate, if known devices are considered, a significant loss in the energy of the re-emitted radiation by absorption in the material of the device and thus the output of the device is extremely decreased.

If glass is considered to be the transparent material of choice in such devices and if the glazed area is to be increased enough to achieve a size that is large enough for architectural applications in particular, it is clear that this effect of absorption of the re-emitted radiation is critical.

In addition, in order to avoid the visible domain for the aforementioned reasons, it would be advantageous for the absorbed and/or re-emitted radiation to be located in the UV or near-infrared domain. In the case of a conversion towards longer wavelengths, it would be judicious to use the near-infrared domain for the re-emitted radiation. Thus, if the conventional soda-lime glass called “clear” glass is considered as the transparent material in such devices, the latter has a coefficient of absorption of 30 m⁻¹ at the wavelength 850 nm. The consequence of such a coefficient of absorption is that after only 2.3 cm of travel through the glass, 50% of the re-emitted radiation has already been reabsorbed and, after only 5.3 cm of travel through the glass, there remains less than 1% of the initially re-emitted radiation. What is called “extra clear” soda-lime glass, having a low iron content, has, for its part, a coefficient of absorption of 4 m⁻¹ at the wavelength 850 nm. The consequence of such a coefficient of absorption is that after only 23 cm of travel through the glass, 50% of the re-emitted radiation has already been reabsorbed and, after 115 cm of travel through the glass, there remains less than 1% of the initially re-emitted radiation.

One of the ways to solve this major problem would be to increase the generating area (therefore the number and/or size of the photovoltaic cells). In conventional PV devices, increasing the generating area automatically leads to a drastic increase in the total cost of the device and, potentially, requires the major faces of the matrix to be occupied (due to a lack of space on the edge faces thereof) thereby, necessarily, then unbearably impacting the general appearance of the PV device, which at least partially loses its transparency (as is the case with conventional BIPV devices including opaque zones corresponding to solar cells placed on their major faces). The device of U.S. Pat. No. 4,727,425 attempts to get around this drawback by specifically and locally increasing the thickness of the edge face of the luminescent matrix and thus allowing the area of the solar cells to be increased but (i) the negative impact on cost is still present with respect to the preceding solution and (ii) the local increase in the thickness of an edge face cannot be achieved easily with each and every type of substrate/matrix (and certainly not in the case of a transparent matrix made of glass).

There is therefore a need to provide the photovoltaic market with a glazing unit for BIPV applications that is efficient, transparent in the visible and large in size. Another market need is to provide a functional glazing unit (for architectural or automotive applications) that is transparent in the visible and that is “autonomous”, i.e. able to produce all the power/electricity that it requires to operate. One example of such a functional glazing unit is a window incorporating a detector/sensor or an electrochromic layer.

### 3. OBJECTIVES OF THE INVENTION

The objective of the invention, in at least one of its embodiments, is to provide a photovoltaic device allowing the drawbacks of the PV devices of the prior art to be remedied.

In particular, the objective of the invention, in at least one of its embodiments, is to provide a photovoltaic device allowing the loss of re-emitted radiation by absorption to be very greatly decreased.

The objective of the invention, in at least one of its embodiments, is also to provide a photovoltaic device using re-emitted radiation that is invisible to the eye.

Another objective of the invention, in at least one of its embodiments, is to provide a photovoltaic device that allows the transparency of said device to be maintained when it is seen from its major faces.

Finally, another objective of the invention is to provide a concentrating photovoltaic device that is inexpensive to produce.

### 4. SUMMARY OF THE INVENTION

The invention relates to a photovoltaic device intended to convert into electricity incident radiation ϕ1 of a wavelength λ1 comprised between 280 and 1000 nm, comprising:
(i) an assembly comprising
   a glass sheet V1 having two major faces f1 and f2, the face f1 being that via which the incident radiation ϕ1 penetrates into the assembly and said sheet V1 being transparent to said incident radiation ϕ1;
   a functional layer F covering the major face f2 of the sheet V1 and comprising a matrix in which are dispersed luminescent elements capable of absorbing said incident radiation ϕ1 of wavelength λ1 and of re-emitting it with a wavelength λ2 longer than λ1 and comprised between 800 and 1400 nm; and
(ii) at least one photovoltaic cell (C1, C2, C3, . . . ) at which the re-emitted radiation of wavelength λ2 arrives and which is sensitive to the wavelength λ2;
in which device the glass sheet V1 has a coefficient of absorption at the wavelength λ2 lower than 3 m⁻¹.

Thus, the invention is based on a completely novel and inventive approach. The inventors have indeed demonstrated that it is possible to obtain a very efficient PV device allowing, if desired, the transparency required for architectural applications to be achieved, and preserving its efficiency even when its dimensions are very large (about a plurality of metres), by combining, in an assembly, a glass sheet associated with a functional layer including luminescent elements capable of absorbing incident radiation of wavelength λ1 and of re-emitting it with a wavelength λ2 longer than λ1 and located between 800 and 1400 nm; the glass sheet being highly transmissive at the wavelength λ2.

In the invention, this particular glass sheet-functional layer assembly plays the role of a very effective waveguide for the radiation re-emitted isotropically by the luminescent elements, so as to gain a maximum of benefit from this new radiation and to harvest therefrom a maximum of energy usable by the photovoltaic cells. Thus, certain advantages are achieved: firstly, the photovoltaic cells may, at equal power, be decreased in number/area since the output of the device is improved with respect to the PV devices of the prior art, thereby allowing the cost of the device to be decreased and/or enough space to be found on the edge face of the assembly for the cells to be positioned thereon, thereby then allowing a “transparent” device usable as an architectural glazing unit to be obtained

Throughout the present text, when a range is indicated, the end values are included. In addition, all the integer values and sub-ranges in a numerical range are expressly included as if explicitly written. Also throughout the present text, the content values are in percentages, unless explicitly specified otherwise (for example, in ppm). Similarly, also throughout the present text, all the content values in percentages are by weight, i.e. expressed relative to the total weight of the glass.

Other features and advantages of the invention will become more clearly apparent on reading the following description, examples and figures, in which:

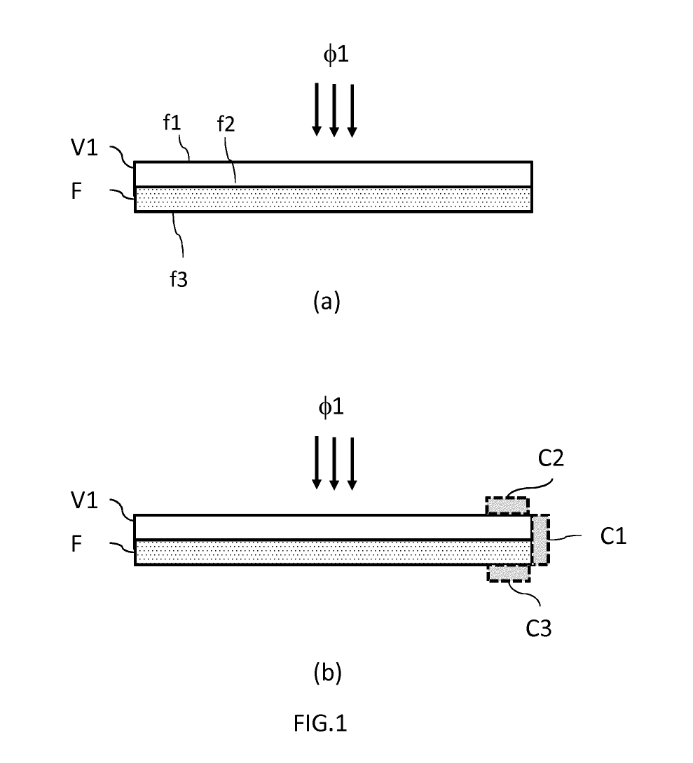

FIG. 1 shows a schematic of the device according to the invention;

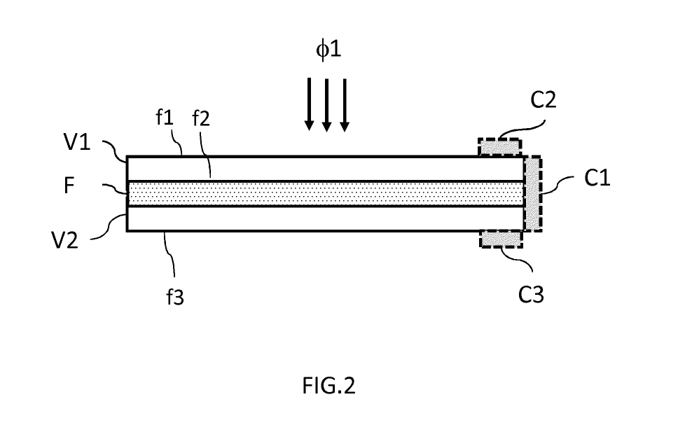

FIG. 2 is a variant embodiment of the device in FIG. 1;

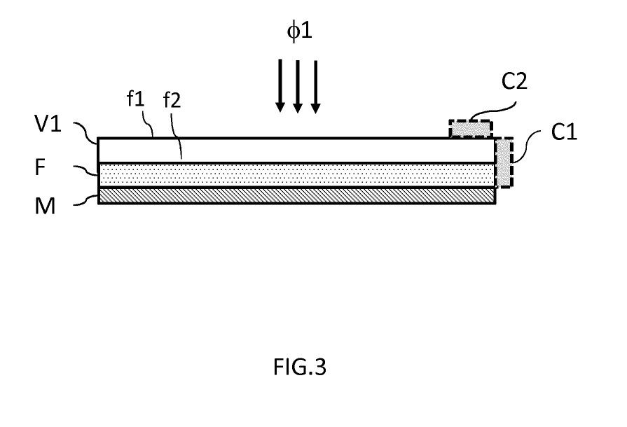

FIG. 3 is a variant embodiment of the device in FIG. 1;

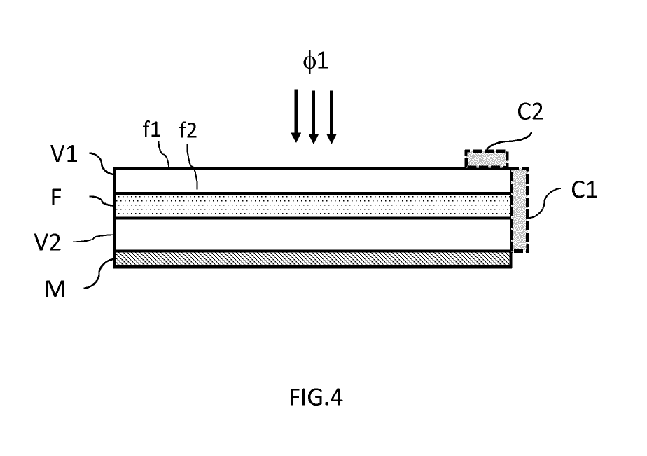

FIG. 4 is a variant embodiment of the device in FIG. 2;

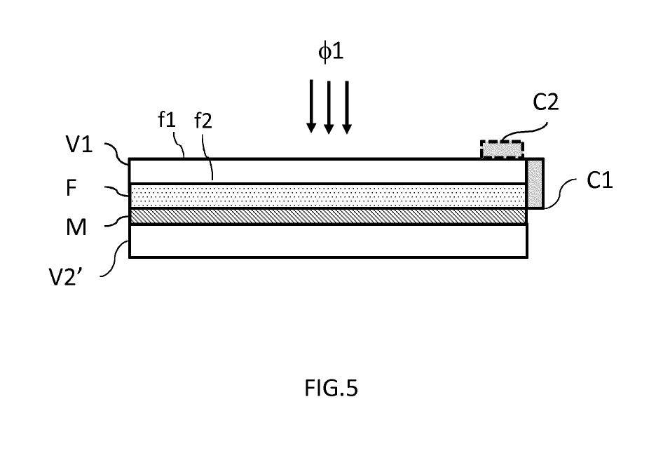

FIG. 5 is a variant embodiment of the device in FIG. 3;

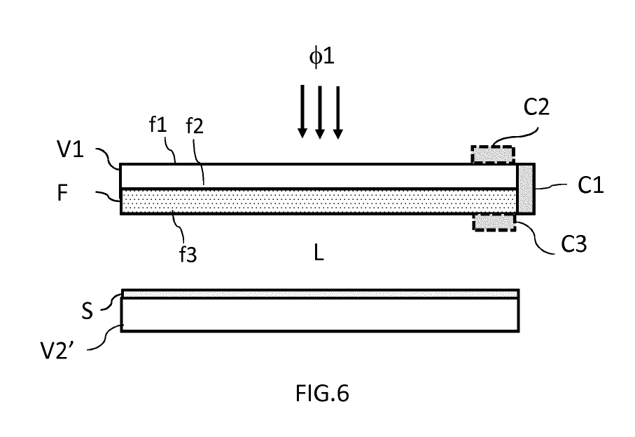

FIG. 6 is a variant embodiment of the device in FIG. 1;

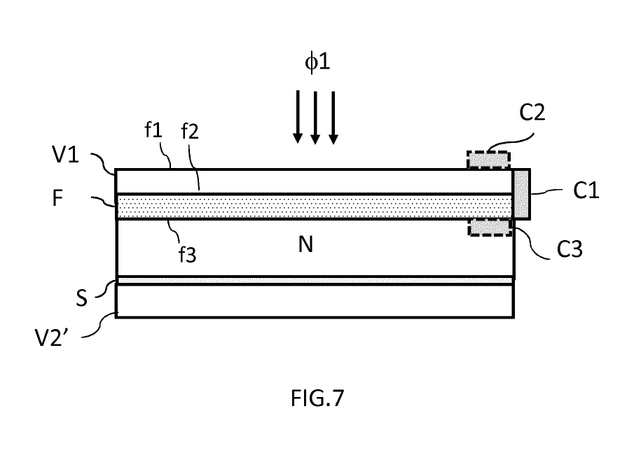

FIG. 7 is a variant embodiment of the device in FIG. 1; and

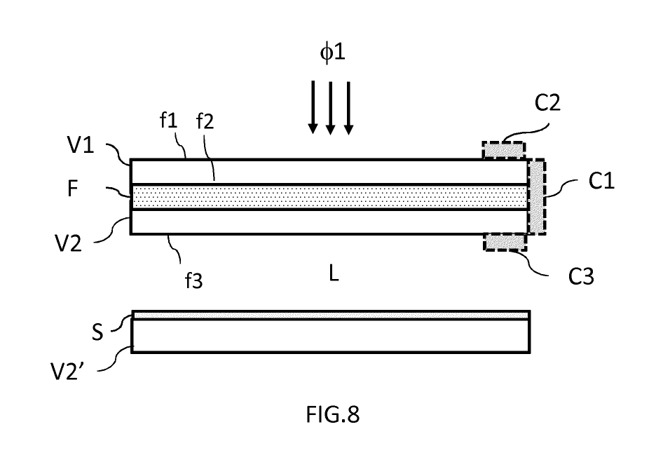

FIG. 8 is a variant embodiment of the device in FIG. 2.

The assembly according to the invention, illustrated in FIG. 1(a), comprises:
a glass sheet V1 having two major faces f1 and f2, the face f1 being that via which the incident radiation penetrates into the assembly and said sheet V1 being transparent to said incident radiation ϕ1; and
a functional layer F covering the face f2 of the sheet V1 and comprising a matrix in which are dispersed luminescent elements (LE) capable of absorbing said incident radiation ϕ1 of wavelength λ1 and of re-emitting it with a wavelength λ2 longer than λ1 and comprised between 800 and 1400 nm.

The assembly according to the invention illustrated in FIG. 1 comprises two external major faces f1 and f3 and secondary faces corresponding to the edge faces of the assembly and that have a significantly smaller area than the area of said major faces f1 and f3.

The glass sheet V1 according to the invention is transparent to the incident radiation ϕ1 of wavelength λ1. By transparent to the incident radiation ϕ1, what is meant according to the invention is that the glass sheet has a transmittance at the wavelength λ1 higher than 10%.

The glass sheet V1 may be a glass sheet obtained by a float process, a drawing process, or a rolling process or any other known process for manufacturing a glass sheet from a molten glass composition. Preferably, the glass sheet V1 is a float glass sheet. The glass sheet V1 may have a thickness varying between 0.1 and 25 mm. Advantageously the glass sheet V1 according to the invention may have a thickness between 4 and 12 mm. The glass sheet V1 according to the invention is made of glass possibly belonging to various categories in terms of base composition. The glass can thus be a glass of soda-lime-silica, aluminosilicate or borosilicate type, and the like. Preferably, the base composition of the glass sheet V1 comprises, in a content expressed in percentage by total weight of glass:

| | |
|---|---|
| SiO₂ | 55-85% |
| Al₂O₃ | 0-30% |
| B₂O₃ | 0-20% |
| Na₂O | 0-25% |
| CaO | 0-20% |
| MgO | 0-15% |
| K₂O | 0-20% |
| BaO | 0-20%. |

More preferably, the base composition of the glass sheet V1 comprises, in a content expressed in percentage by total weight of glass:

| | |
|---|---|
| SiO₂ | 55-78% |
| Al₂O₃ | 0- 18% |
| B₂O₃ | 0-18% |
| Na₂O | 0-20% |
| CaO | 0-15% |
| MgO | 0-10% |
| K₂O | 0-10% |
| BaO | 0-5%. |

Most preferably and for reasons of lower production costs, the glass sheet V1 according to the invention is a sheet of soda-lime-silica glass. Advantageously, according to this embodiment, the base composition of the glass sheet V1 comprises, in a content expressed in percentage by total weight of glass:

| | |
|---|---|
| SiO₂ | 60-75% |
| Al₂O₃ | 0-6% |
| B₂O₃ | 0-4% |
| CaO | 0-15% |
| MgO | 0-10% |
| Na₂O | 5-20% |
| K₂O | 0-10% |
| BaO | 0-5%. |

In addition to its base composition, the glass sheet V1 may comprise other components, of nature and quantity tailored to the sought-after effect.

According to the invention the glass sheet V1 advantageously has a very low coefficient of absorption at the wavelength λ2, which is comprised between 800 and 1400 nm, compared to usual glasses (such as what is called “clear” or even “extra clear” glass).

To quantify the good transmittance of the glass in the infrared domain at the specific wavelengths of interest for the applications in question, in the present description the coefficient of absorption at the wavelength of interest, i.e. at the wavelength of re-emission of the luminescent elements (in particular, in the near-infrared wavelength range extending from 800 to 1400 nm) will be used. The coefficient of absorption is defined by the ratio of the absorbance to the length of the optical path traveled by electromagnetic radiation in a given medium. It is expressed in m⁻¹. It is thus independent of the thickness of the material but it is a function of the wavelength of the radiation absorbed and of the chemical nature of the material.

In the case of glass, the coefficient of absorption (μ) at a chosen wavelength λ may be calculated from a measurement of transmittance (T) and from the refractive index n of the material (thick=thickness), the values of n, ρ and T depending on the chosen wavelength λ:

$$μ = - \frac{1}{thick} \cdot ln [ \frac{- {( 1 - ρ )}^{2} + \sqrt{{( 1 - ρ )}^{4} + 4 \cdot {T}^{2} \cdot {ρ}^{2}}}{2 \cdot T \cdot {ρ}^{2}} ]$$

where ρ=(n−1)²/(n+1)².

In particular, the glass sheet V1 of the invention has a coefficient of absorption at the wavelength λ2 lower than 3 m⁻¹. Preferably, the glass sheet V1 has a coefficient of absorption at the wavelength λ2 lower than 2 m⁻¹, or even lower than 1.5 m⁻¹ and, even more preferably, lower than 1 m⁻¹, or even lower than 0.8 m⁻¹.

One way proposed in the invention of obtaining a glass sheet that is very transparent at the wavelength λ2 consists in combining, in the composition of the glass, both a low iron and a low chromium content, said contents lying in a specific range of contents.

Thus, according to one embodiment of the invention, the glass sheet V1 advantageously has a composition that comprises, in a content expressed in percentage by total weight of glass:

| | |
|---|---|
| Total iron (expressed in the form of Fe₂O₃) | 0.002-0.06%; |
| Cr₂O₃ | 0.0001-0.06%. |

Such glass compositions combining a low iron and chromium scontent have demonstrated a particularly good performance in terms of transmittance in the 800-1400 nm range and exhibit a high transparency in the visible and a not very pronounced tint, close to a what is called “extra-clear” glass. These compositions are described in international patent applications WO2014128016A1, WO2014180679A1, WO2015011040A1, WO2015011041A1, WO2015011042A1, WO2015011043A1 and WO2015011044A1, which are incorporated by reference into the present patent application.

According to this first particular embodiment, the composition preferably comprises a chromium (expressed in the form of Cr₂O₃) content ranging from 0.002% to 0.06% by weight with respect to the total weight of the glass. Such chromium contents allow the transmittance of the glass sheet in the 800-1400 nm range to be further improved.

According to another embodiment of the invention, the glass sheet V1 has a composition that comprises, in a content expressed in percentage by total weight of glass:

| | |
|---|---|
| Total iron (expressed in the form of Fe₂O₃) | 0.002-0.06%; |
| Cr₂O₃ | 0.0015-1% |
| Co | 0.0001-1%. |

Such glass compositions based on chromium and cobalt have demonstrated a particularly good performance in terms of transmittance in the 800-1400 nm range, while creating interesting possibilities in terms of aesthetics/colour. These compositions are described in European patent application no. 13 198 454.4, which is incorporated by reference into the present patent application.

Alternatively to chromium, other solutions combining, in a glass composition, a low iron content and one or more other components in specific quantities, allow a glass sheet that is very transparent in the 800-1400 nm range to be obtained, with little or no impact on its aesthetics and colour. Such compositions are described in European patent application no. 13 193 345.9, which is incorporated by reference into the present patent application.

The glass sheet V1 preferably has a transmittance at the wavelength λ1 higher than 20%. Preferably, the glass sheet V1 has a transmittance at the wavelength λ1 higher than 30% or, even better still, higher than 40%. More preferably, the glass sheet V1 has a transmittance at the wavelength λ1 higher than 50% or even higher than 60%. Most preferably, the glass sheet V1 has a transmittance at the wavelength λ1 higher than 70% or even higher than 80%. It will of course be clear that the higher the transmittance of the sheet V1 at λ1, the greater the benefit to the overall output of the device of the invention.

Advantageously, the glass sheet V1 preferably has a light transmittance TLA4 higher than 10% or, even better still, higher than 20%. Preferably, the glass sheet V1 has a light transmittance TLA4 higher than 30% or, even better still, higher than 40%. More preferably, the glass sheet V1 has a light transmittance TLA4 higher than 50 or even higher than 60%. Most preferably, the glass sheet V1 has a light transmittance TLA4 higher than 70% or even higher than 80%. This has the advantage of allowing the device according to the invention to be used as a particularly aesthetic glazing unit in the architectural field.

In the device of the invention, the photovoltaic cells according to the invention may be positioned, as illustrated in FIG. 1(b), (i) on one or more edge faces of the assembly (C1), and/or (ii) on the major face f1 (C2), and/or (iii) on the major face f3 (C3).

According to one embodiment of the device according to invention, the photovoltaic cells are positioned only on one or more edge faces of the assembly (C1). This is particularly advantageous in order to obtain a device the aesthetics of which are not deteriorated by the sight of the solar cells and that is therefore usable as an architectural glazing unit.

The photovoltaic cells according to the invention may advantageously be the cells known as crystalline-silicon cells or even “CIGS” cells, or any other type of photovoltaic cells sensitive to the wavelengths λ2.

According to one embodiment of the invention illustrated in FIG. 2, the device also comprises a glass sheet V2 that covers the functional layer F and that has a coefficient of absorption at the wavelength λ2 lower than 3 m⁻¹. This makes it possible to make the assembly more solid and durable, the functional layer being completely protected from the exterior environment by the glass, without affecting the good operation of the PV device or its performance.

In the device embodiment illustrated in FIG. 2, the photovoltaic cells may be positioned (i) on one or more edge faces of the assembly (C1), and/or (ii) on the external major face f1 (C2), and/or (iii) on the external major face f3 (C3). Preferably, the photovoltaic cells are positioned only on one or more edge faces of the assembly in FIG. 2 (C1).

According to one embodiment of the invention, which embodiment is illustrated in FIG. 3 and which is a variant of the embodiment in FIG. 1, the device comprises a mirror layer M covering said functional layer F and located on an external face.

The embodiments of the invention illustrated in FIGS. 4 and 5 are variants of the embodiments in FIGS. 2 and 3, respectively.

In FIG. 4, the device according to the invention comprises:
a glass sheet V2 that covers the functional layer F and that has a coefficient of absorption at the wavelength λ2 lower than 3 m⁻¹; and
a mirror layer M covering said glass sheet V2 and located on an external face.

In FIG. 5, which shows a variant of FIG. 3, the device according to the invention also comprises:
a glass sheet V2′; and
a mirror layer M covering the functional layer F and interposed between said functional layer and the sheet V2′.

The mirror layer M according to the embodiments in FIGS. 3, 4 and 5 may for example be what is called a “triple silver” (Ag3) layer or any layer that reflects the wavelength λ2. Thus, reflection towards the interior of the assembly is increased and the PV output of the device improved thereby.

According to the embodiments in FIGS. 3, 4 and 5, the photovoltaic cells may be positioned (i) on one or more edge faces of the assembly (C1), and/or (ii) on the external major face f1 (C2). Preferably, the photovoltaic cells are positioned only on one or more edge faces of the assembly in FIG. 3, 4 or 5 (C1).

According to another embodiment of the invention illustrated in FIG. 6, the device according to the invention forms an insulating multiple glazing unit and comprises:
at least one glass sheet V2′ spaced apart from the functional layer F by a gas-filled cavity L (for example filled with air); and
a layer S covering said glass sheet V2′ and located inside the insulating multiple glazing unit on the side of the cavity L, said layer being a solar-control or low-emissivity (“low-e”) layer.

In the device embodiment illustrated in FIG. 6, the photovoltaic cells may be positioned (i) on one or more edge faces of the assembly (C1), and/or (ii) on the external major face f1 (C2), and/or (iii) on the face f3 (C3). Preferably, the photovoltaic cells are positioned only on one or more edge faces of the assembly in FIG. 6 (C1).

According to another embodiment of the invention illustrated in FIG. 7, the device according to the invention furthermore comprises:
a low-refractive-index layer N covering the functional layer F;
a solar-control or low-emissivity (“low-e”) layer S covering the low-refractive-index layer N; and
a glass sheet V2′ covering the layer S.

In the device embodiment illustrated in FIG. 7, the photovoltaic cells may be positioned (i) on one or more edge faces of the assembly (C1), and/or (ii) on the external major face f1 (C2), and/or (iii) on the face f3, the cells then being encapsulated in the material of the layer N (C3). Preferably, the photovoltaic cells are positioned only on one or more edge faces of the assembly in FIG. 7 (C1).

The embodiment of the invention illustrated in FIG. 8 is a variant of the embodiment in FIG. 2. According to this variant, the device forms an insulating multiple glazing unit and furthermore comprises:
a glass sheet V2 that covers the functional layer F and that has a coefficient of absorption at the wavelength λ2 lower than 3 m⁻¹;
at least one glass sheet V2′ spaced apart from the functional layer F by a gas-filled cavity L (for example filled with air); and
a layer S covering said glass sheet V2′ and located inside the insulating multiple glazing unit on the side of the cavity L; said layer being a solar-control or low-emissivity (“low-e”) layer.

In the embodiments in FIGS. 2, 4 and 8 comprising a glass sheet V2, the glass sheet V2 preferably has a coefficient of absorption at the wavelength λ2 lower than 2 m⁻¹, or even lower than 1.5 m⁻¹ and, even more preferably, lower than 1 m⁻¹, or even lower than 0.8 m⁻¹. In addition, the glass sheet V2 preferably has a light transmittance TLA4 higher than 10% or, even better still, higher than 20%. Preferably, the glass sheet V2 has a light transmittance TLA4 higher than 30% or, even better still, higher than 40%. More preferably, the glass sheet V2 has a light transmittance TLA4 higher than 50 or even higher than 60%. Most preferably, the glass sheet V2 has a light transmittance TLA4 higher than 70% or even higher than 80%. This has the advantage of allowing the device according to the invention to be used as a particularly aesthetic glazing unit in the architectural field. The glass sheet V2 may be a glass sheet obtained by a float process, a drawing process, or a rolling process or any other known process for manufacturing a glass sheet from a molten glass composition. Preferably, the glass sheet V2 is a float glass sheet. The glass sheet V2 may have a thickness varying between 0.1 and 25 mm. Advantageously the glass sheet V2 according to the invention may have a thickness between 4 and 12 mm. The glass sheet V2 is made of glass possibly belonging to various categories in terms of base composition. The glass can thus be a glass of soda-lime-silica, aluminosilicate or borosilicate type, and the like. Preferably, the base composition of the glass sheet V2 comprises, in a content expressed in percentage by total weight of glass:

| | |
|---|---|
| SiO₂ | 55-85% |
| Al₂O₃ | 0-30% |
| B₂O₃ | 0-20% |
| Na₂O | 0-25% |
| CaO | 0-20% |
| MgO | 0-15% |
| K₂O | 0-20% |
| BaO | 0-20%. |

More preferably, the base composition of the glass sheet V2 comprises, in a content expressed in percentage by total weight of glass:

| | |
|---|---|
| SiO₂ | 55-78% |
| Al₂O₃ | 0-18% |
| B₂O₃ | 0-18% |
| Na₂O | 0-20% |
| CaO | 0-15% |
| MgO | 0-10% |
| K₂O | 0-10% |
| BaO | 0-5%. |

Most preferably, the glass sheet V2 according to the invention is a sheet of soda-lime-silica glass. Advantageously, according to this embodiment, the base composition of the glass sheet V2 comprises, in a content expressed in percentage by total weight of glass:

| | |
|---|---|
| SiO₂ | 60-75% |
| Al₂O₃ | 0-6% |
| B₂O₃ | 0-4% |
| CaO | 0-15% |
| MgO | 0-10% |
| Na₂O | 5-20% |
| K₂O | 0-10% |
| BaO | 0-5%. |

In addition to its base composition, the glass sheet V2 may comprise other components, of nature and quantity tailored to the sought-after effect.

In addition, the glass sheet V2 may advantageously have a composition that comprises, in an amount expressed as a percentage of the total weight of glass:

| | |
|---|---|
| Total iron (expressed in the form of Fe₂O₃) | 0.002-0.06%; |
| Cr₂O₃ | 0.0001-0.06%. |

According to this particular embodiment, the composition of the glass sheet V2 preferably comprises a chromium (expressed in the form of Cr₂O₃) content ranging from 0.002% to 0.06% by weight with respect to the total weight of the glass.

The glass sheet V2 may also have a composition that comprises, in an amount expressed as a percentage of the total weight of glass:

| | |
|---|---|
| Total iron (expressed in the form of Fe₂O₃) | 0.002-0.06%; |
| Cr₂O₃ | 0.0015-1% |
| Co | 0.0001-1%. |

Alternatively to chromium, other compositions suitable for the glass sheet V2 are described in European patent application no. 13 193 345.9.

In the embodiments of FIGS. 2, 4 and 8, the glass sheets V1 and V2 may have substantially the same composition or, alternatively, they may be of different compositions.

In the embodiments in FIGS. 5, 6, 7 and 8, the glass sheet V2′ may be a glass sheet obtained by a float process, a drawing process, or a rolling process or any other known process for manufacturing a glass sheet from a molten glass composition. Preferably, the glass sheet V2′ is a float glass sheet. The glass sheet V2′ may have a thickness varying between 0.1 and 25 mm. Advantageously the glass sheet V′2 according to the invention may have a thickness between 4 and 12 mm. The glass sheet V2′ is made of glass possibly belonging to various categories in terms of base composition. The glass may thus be a soda-lime-silica glass, an aluminosilicate glass, a borosilicate glass, etc.

The functional layer F according to the invention covers the second major face f2 of the sheet V1 and comprises a matrix in which are dispersed the luminescent elements. By “dispersed”, what is meant according to the invention is that the luminescent elements are dissolved and/or in suspension in particle form in the matrix.

The matrix of the invention may be made of any type of material capable of allowing the luminescent elements to be dispersed and of allowing adhesion thereof to a glass sheet, and even lamination thereof. It may be a question, for example, of a plastic, such as a sheet of PVB, of PU, of ionomer or of EVA. It may also be a layer of transparent lacquer (clearcoat), such as for example a layer of epoxy resin or methacrylate.

Advantageously, the functional layer F according to the invention has a coefficient of absorption at the wavelength λ2 lower than 5 m⁻¹ and preferably lower than 3 m⁻¹. More preferably, the functional layer F according to the invention has a coefficient of absorption at the wavelength λ2 lower than 2 m⁻¹, or even lower than 1.5 m⁻¹ and, even more preferably, lower than 1 m⁻¹, or even lower than 0.8 m⁻¹.

Advantageously, the functional layer F according to the invention has a refractive index higher than 1.3; 1.4; 1.5 or even 1.6 or 1.7; or indeed higher than 2. This has the advantage of limiting the proportion of the re-emitted radiation that escapes from the glass directly without being propagated by total internal reflection therein

Advantageously, the functional layer F preferably has a light transmittance TLA4 higher than 10% or, even better still, higher than 20%. Preferably, the functional layer F has a light transmittance TLA4 higher than 30% or, even better still, higher than 40%. More preferably, the functional layer F has a light transmittance TLA4 higher than 50 or even higher than 60%. Most preferably, the functional layer F has a light transmittance TLA4 higher than 70% or even higher than 80%. This has the advantage of allowing the device according to the invention to be used as a particularly aesthetic glazing unit in the architectural field.

The luminescent elements according to the invention are capable of absorbing the incident radiation ϕ1 of wavelength λ1 and of re-emitting it with a wavelength λ2 longer than λ1 and comprised between 800 and 1400 nm.

The luminescent elements according to the invention may be of organic and/or inorganic nature but are preferably of inorganic nature for reasons of stability over time. The luminescent elements according to the invention may (i) take the form of particles dispersed and in suspension in said matrix and/or (ii) be dissolved in the material of the matrix. When the luminescent elements take the form of particles, the size of said particles will ideally be chosen so as to prevent them having too great an impact on the aesthetics and transparency of the assembly according to the invention. The concentration of the luminescent elements in the matrix is ideally chosen in order to achieve a balance between the impact on the aesthetics/transparency of the assembly and the PV performance of the device, while taking into account the compatibility of the luminescent elements and the material of the matrix. By way of example, concentrations of about 0.01% by weight to 0.5 or even 1% by weight are often quite enough.

Examples of luminescent elements (LE) usable in the invention are given in the following table, which also mentions the corresponding wavelengths λ1 and λ2.

The functional layer according to the invention may comprise a mixture of different luminescent elements.

According to one advantageous embodiment of the invention, the wavelength λ1 is comprised between 280 and 380 nm. By choosing a λ1 outside of the visible and in particular in the UV, it is possible to prevent the device from appearing to have a colour, this often being undesirable in architectural applications.

TABLE 1

| LE | λ1 (nm) | λ2 (nm) |
|---|---|---|
| Yttrium oxide doped with one or more | ~980 | ~1000 |
| rare-earths and sensitized ytterbium, | | |
| Y203:RE, Yb | | |
| Neodymium-doped yttrium phosphate, | 940-980 | ~1060 |
| YP04:Nd | | |
| Copper-doped zinc cadmium sulphide, | 300-550 | ~940 |
| (Zn, Cd)S:Cu | | |

According to one advantageous embodiment of the invention, the wavelength λ1 is comprised between 750 and 950 nm. By choosing a λ1 outside of the visible and in particular in the near infrared, it is possible to prevent the device from appearing to have a colour, this often being undesirable in architectural applications.

Ideally, the difference between the two wavelengths λ1 and λ2 is large enough to prevent energy-loss effects due to reabsorption of the radiation ϕ2 and, in particular, preferably, (λ2−λ1)≥20 nm, and even better still, (λ2−λ1)≥50 nm.

Advantageously, when 11 is located in the near infrared, the wavelength λ2 is longer than 900 nm if it is desired to prevent λ1 and λ2 from being too close together and thus to prevent reabsorption. Also advantageously, the wavelength λ2 is shorter than 1200 nm because the conventional commercially available solar cells (crystalline Si and CIGS cells) are insensitive beyond this wavelength. Very advantageously, the wavelength λ2 is comprised between 900 and 1200 nm.

The embodiment combining a wavelength λ1 comprised between 280 and 380 nm and a wavelength λ2 comprised between 900 and 1200 nm is advantageous.

The embodiment combining a wavelength λ4 between 280 and 380 nm, with a wavelength λ2 comprised between 900 and 1200 nm and (λ2−λ4)≥50 nm is especially advantageous. We will thus mention (Zn,Cd)S:Cu as being a particularly suitable choice by way of electroluminescent element in the present invention.

The embodiment combining a wavelength λ4 between 750 and 950 nm, with a wavelength λ2 comprised between 900 and 1200 nm and (λ2−λ4)≥50 nm is also especially advantageous.

The present invention of course also covers the case where the incident radiation is composed of a plurality of constituents ϕ1, ϕl′, ϕ1″, . . . of wavelengths λ1, λ1′, λ1″, . . . comprised between 280 and 1000 nm, which wavelengths are converted by luminescent elements into wavelengths λ2, λ2′, λ2″, . . . comprised between 800 and 1400 nm; the device then comprising at least one photovoltaic cell sensitive to λ2, at least one photovoltaic cell sensitive to λ2′, at least one photovoltaic cell sensitive to λ2″, etc.; it being understood that said photovoltaic cells may or may not be specific to a single wavelength from λ2, λ2′, λ2″, . . . (one cell possibly being sensitive to a plurality of wavelengths among λ2, λ2′, λ2″, . . . ).

Advantageously, according to one embodiment, the device of the invention has an overall light transmittance higher than 10%, and preferably higher than 20%, or even better still higher than 30%, or even higher than 40%. More preferably, the device has an overall light transmittance higher than 50%, 60% or 70%, and most preferably higher than 80%. This has the advantage of allowing the device according to the invention to be used as a particularly aesthetic glazing unit in the architectural field.

Advantageously, the glass sheet V1 may be covered externally with an antireflection treatment or layer (on face f1) thus allowing a maximum of incident radiation to penetrate into the photovoltaic device.

Depending on the desired properties and/or applications other layers/other treatments may be deposited/carried out on one and/or other face of the glass sheet(s) of the device of the invention. For example, in the case of an architectural application requiring a high level of solar protection, the device of the invention may be combined with a semitransparent photovoltaic film. This has the advantage of combining the output of the device of the invention and the output of the photovoltaic film while providing an adequate level of solar protection without using absorbent glass.

1: A photovoltaic device suitable to convert into electricity incident radiation Φ1 of a wavelength λ1 comprised between 280 and 1000 nm, comprising:
an assembly comprising
(a) a glass sheet VI having two major faces f1 and f2, the face f1 being that via which the incident radiation penetrates into said assembly and said sheet VI being transparent to said incident radiation Φ1;
(b) a functional layer F covering the major face f2 of the sheet V1 and comprising a matrix in which are dispersed luminescent elements capable of absorbing said incident radiation Φ1 of wavelength λ1 and of re-emitting it with a wavelength λ2 longer than λ1 and comprised between 800 and 1400 nm; and
at least one photovoltaic cell at which the re-emitted radiation of wavelength λ2 arrives and which is sensitive to the wavelength λ2,
in which device the glass sheet VI has a coefficient of absorption at the wavelength λ2 lower than 3 m⁻¹.

2: The photovoltaic device according to claim 1, wherein the wavelength λ1 is comprised between 280 and 380 nm.

3: The photovoltaic device according to claim 1, wherein the wavelength λ1 is comprised between 750 and 950 nm.

4: The photovoltaic device according to claim 1, wherein: (λ2−λ1)≥20 nm.

5: The photovoltaic device according to the claim 4, wherein: (λ2−λ1)≥50 nm.

6: The photovoltaic device according to claim 1, wherein said photovoltaic cells are positioned only on one or more edge faces of the assembly.

7: The photovoltaic device according to claim 1, wherein the glass sheet V1 has a coefficient of absorption at the wavelength λ2 lower than 2 m⁻¹.

8: The photovoltaic device according to claim 7, wherein the glass sheet V1 has a coefficient of absorption at the wavelength λ2 lower than 1.5 m⁻¹.

9: The photovoltaic device according to claim 8, wherein the glass sheet V1 has a coefficient of absorption at the wavelength λ2 lower than 1 m⁻¹.

10: The photovoltaic device according to claim 1, wherein the functional layer F has a coefficient of absorption at the wavelength λ2 lower than 5 m⁻¹.
